(19) United States
(12) Patent Application Publication
(10) Pub. No.: US 2009/0115022 A1
(43) Pub. Date: May 7, 2009

(54) SEMICONDUCTOR DEVICE

(75) Inventors: Yasutaka NAKASHIBA, Kanagawa (JP); Toshiyuki Takewaki, Kanagawa (JP)

Correspondence Address: YOUNG & THOMPSON, 209 Madison Street, Suite 500, ALEXANDRIA, VA, 22314, US

(73) Assignee: NEC ELECTRONICS COROPORATION, Kanagawa (JP)

(21) Appl. No.: 12/263,650

(22) Filed: Nov. 3, 2008

(30) Foreign Application Priority Data
Nov. 6, 2007 (JP) 2007-288291

(51) Int. Cl. H01L 29/00

(52) U.S. Cl. 257/531; 257/E29.001

(57) ABSTRACT

A semiconductor device 1 includes: a copper interconnect layer 14 that has an interconnect containing an inductor 141, which is buried in an interconnect trench formed in an insulating layer 21; and copper interconnect layers 11 to 13, which include no inductor and are buried in interconnect trenches formed in other insulating layers 15, 17 and 19, respectively. An average grain size of the inductor 141 is larger than average grain sizes of the interconnects in the copper interconnect layers 11 to 13 that contain no inductor

This application is based on Japanese patent application No. 2007-288,291, the content of which is incorporated hereinto by reference.

### BACKGROUND

1. Technical Field

The present invention relates to a semiconductor device.

2. Related Art

Conventionally, as shown in FIGS. 6 and 7, an inductor 901 is provided in a semiconductor device 900 (see Japanese Patent Laid-Open No. 2004-31,520). FIG. 7 is a cross-sectional view along line VII-VII of FIG. 6. Such inductor 901 is provided in an interconnect layer 904 of an uppermost layer of a multiple-layered interconnect, and is disposed on the insulating layer 903. An insulating layer 905 and an insulating layer 902, which are composed of silicon dioxide (SiO₂), are provided on the inductor 901. Since the inductor 901 is provided on the uppermost interconnect layer 904, a parasitic capacitance between the semiconductor substrate and the inductor 901 is reduced, and the thickness of the inductor 901 is increased to reduce a resistance thereof, thereby providing an enhanced Q factor of the inductor. In addition to above, the inductor 901 and interconnects other than the inductor 901 are conventionally formed by an electrolytic plating process.

### [Patent Document 1]

Japanese Laid-Open Patent Publication No. 2004-31520

### [Patent Document 2]

Japanese Laid-Open Patent Publication No. 2006-196883

### [Patent Document 3]

Japanese Laid-Open Patent Publication No. 2003-109960

The present inventors have recognized as follows. Further improvement in the Q factor is required in recent years, it is difficult to further enhance the Q factor in the conventional semiconductor devices. This is due to the following reason. Since the thickness of the interconnect layer 904 of an uppermost layer is up to about 10 μm, the upper limitation for the thickness of inductor 901 is several micron meter (μm). Consequently, the Q factor of the inductor 901 is reduced. On the other hand, while it is also considered that the linewidth of the inductor is increased for the purpose of providing an increased Q factor of the inductor, such configuration causes an increased space occupied by the inductor in two-dimensional view of the semiconductor device, becoming an obstacle for the miniaturization of the semiconductor device.

### SUMMARY

The present inventors have eagerly studied, and eventually found that the average grain size of the inductor considerably contributes to an improvement in the Q factor. More specifically, it was found that larger average grain size of the inductor is increased, so that the Q factor of the inductor can be enhanced and a miniaturization of the semiconductor device can be achieved.

According to one aspect of the present invention, there is provided a semiconductor device, comprising: a first copper interconnect layer, having an interconnect including an inductor and buried in an interconnect trench formed in a first insulating layer; and a second copper interconnect layer containing no inductor, buried in an interconnect trench formed in a second insulating layer, said second copper interconnect layer having a second interconnect, the first and second copper interconnect layers being stacked, wherein an average grain size of the inductor is larger than an average grain size of the second interconnect of the second copper interconnect layer containing no inductor.

Since the inductor and interconnects other than the inductor are formed by an electrolytic plating process in the conventional semiconductor devices, the average grain size of the inductor of conventional semiconductor devices is equivalent to the average grain size of the interconnect in the interconnect layer containing no inductor. On the contrary, in the present invention, the average grain size of an inductor is larger than the average grain size of the interconnect in the copper interconnect layer containing no inductor. Thus, the average grain size of the inductor is larger, as compared with that of the conventional semiconductor device, and reduced resistance of the inductor can be achieved as compared with the conventional semiconductor devices, thereby providing an enhanced Q factor. In the present invention, reduction of the resistance of the inductor is intended by providing an increased average grain size of the inductor. Thus, larger space is not necessary for the inductor, which does not cause an obstacle for miniaturization of the semiconductor device. In the present invention, each of the grain sizes of the respective grains is obtained by an average of the long axis and the short axis of the grain, and the average grain size is number average of the grain sizes. The grain size or the size of the grain may be determined by observing the grain via transmission electron microscopy (TEM). In addition, in the present invention, when an interconnect includes a seed film and a copper film provided over such seed film, the grain size means a grain size of such copper film except the seed film.

According to the present invention, a semiconductor device, which can achieve an enhanced Q factor of the inductor and can also meet a requirement of a miniaturization of the semiconductor device, is presented.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a cross-sectional view, illustrating a semiconductor device according to an embodiment of the present invention;

FIG. 2 is a plan view, illustrating an inductor of the semiconductor device;

FIG. 3 is a cross-sectional view, illustrating a main part of the semiconductor device;

FIGS. 4A to 4D are cross-sectional views of the semiconductor device, illustrating a process for manufacturing the semiconductor device;

FIG. 5 is a graph, showing a relationship between the average grain size and the resistance of the inductor;

FIG. 6 is a plan view, illustrating a conventional semiconductor device; and

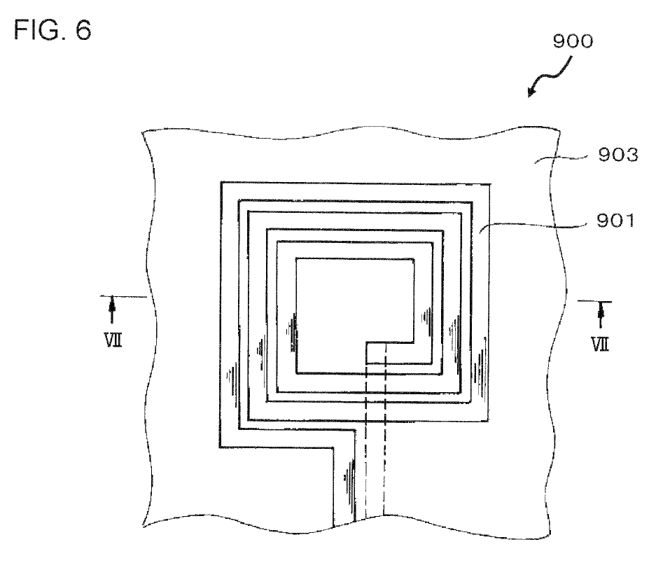

FIG. 7 is a cross-sectional view of the conventional semiconductor device.

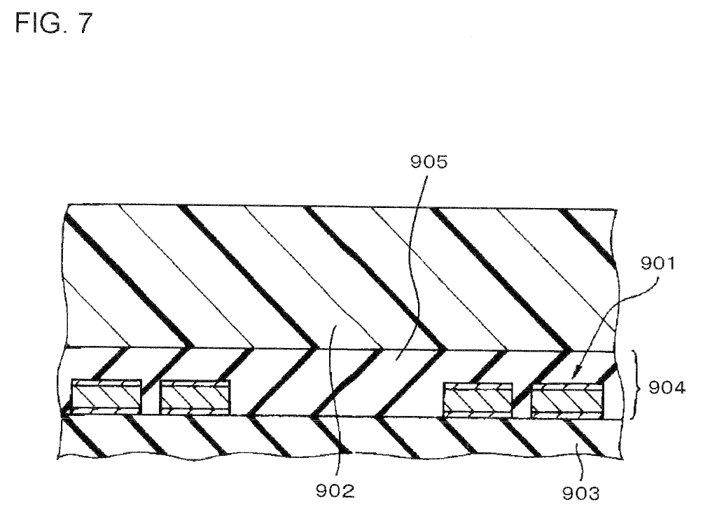

### DETAILED DESCRIPTION

The invention will be now described herein with reference to illustrative embodiments. Those skilled in the art will recognize that many alternative embodiments can be accomplished using the teachings of the present invention and that the invention is not limited to the embodiments illustrated for explanatory purposed.

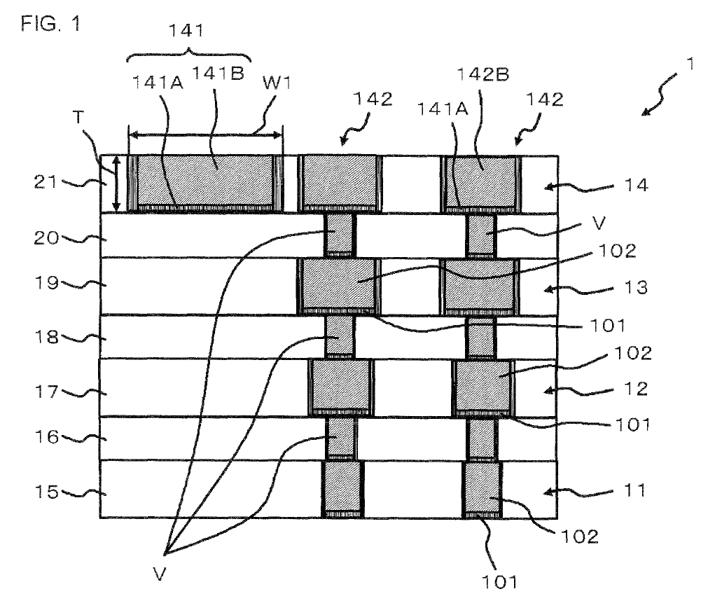

Preferable embodiments of the present invention will be described in reference to the annexed figures. An overview of a semiconductor device 1 of the present embodiment will be described in reference to FIG. 1. The semiconductor device 1 of the present embodiment includes: a copper interconnect layer 14 that has an interconnect containing an inductor 141, which is buried in an interconnect trench formed in an insulating layer 21; and copper interconnect layers 11 to 13, which include no inductor and are buried in interconnect trenches formed in other insulating layers 15, 17 and 19, respectively. An average grain size of the inductor 141 is larger than average grain sizes of the interconnects in the copper interconnect layers 11 to 13 that contain no inductor. In addition to above, taken the visibility into consideration, hatching indicating the cross section of the insulating layer is not shown in FIG. 1.

Next, the semiconductor device 1 of the present embodiment will be fully described in detail. This semiconductor device 1 includes a plurality of copper interconnect layers 11 to 14 that are deposited on a semiconductor substrate, which is not shown here. The copper interconnect layers 11 to 14 may contain copper, and may be of solid copper, and alternatively may be of copper alloy. The respective interconnect layers 11, 12, 13 and 14 are provided in the insulating layers 15, 17, 19 and 21 deposited on the semiconductor substrate, respectively. The interconnect layers 11 to 14 are coupled through vias V. These vias V are provided in insulating layers 16, 18 and 20, which are disposed between the insulating layers 15 and 17, between the insulating layers 17 and 19, and between the insulating layers 19 and 21, respectively. The insulating layers 15, 17, 19 and 21 include the interconnect layers 11 to 14 provided therein, respectively. These vias V may contain copper, and may be of solid copper, and alternatively may be of copper alloy. Here, for example, a low dielectric constant film such as silicon oxycarbide (SiOC) film and the like or SiO₂ films or the like may be employed for the insulating layers 15 to 21.

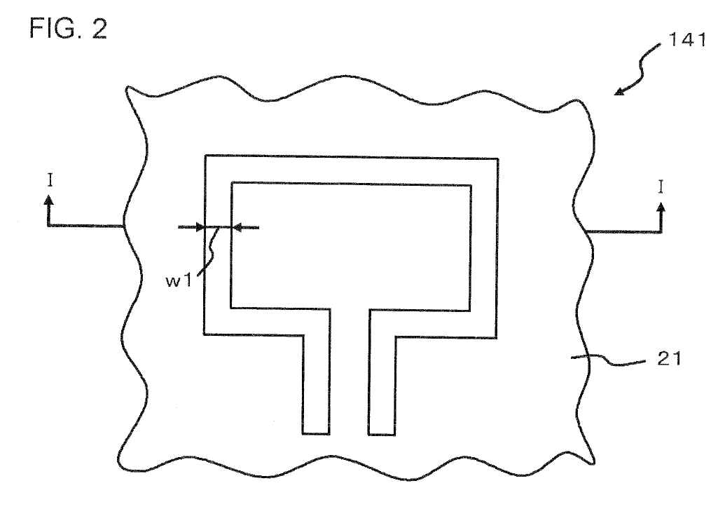

The uppermost interconnect layer 14 includes the inductor 141 and interconnects 142 other than the inductor 141. A two-dimensional geometry of the inductor 141 is an open-ring geometry, as shown in FIG. 2. FIG. 1 illustrates the cross section along line I-I of FIG. 2. The inductor 141 includes a copper seed film 141A and a copper film 141B provided on such seed film 141A.

Here, the inductor 141 is buried in an interconnect trench formed in the insulating layer 21, and a linewidth W1 of the inductor 141 along a cross section perpendicular to an elongating orientation of the inductor 141 is equal to or larger than 5 μm. Though the upper limit of the linewidth W1 of the inductor 141 is not particularly determined, the linewidth may be preferably equal to or smaller than 20 μm, as a space occupied by the inductor 141 is taken into consideration.

The interconnects 142 include a copper seed film 141A and a copper film 142B provided on such seed film 141A. A linewidth of the interconnects 142 is narrower than the linewidth of the inductor 141, and typically, for example, within a range of from 0.5 μm to 3 μm. In the present embodiment, an average grain size of the inductor 141 is larger than an average grain size of the interconnects 142 other than the inductor 141 in the interconnect layer 14. The average grain size of the inductor 141 is typically, for example, within a range of from 4 μm to 20 μm. More preferably, the average grain size may be equal to or larger than 5 μm. Having such configuration, a reduced resistance of the inductor 141 can be ensured.

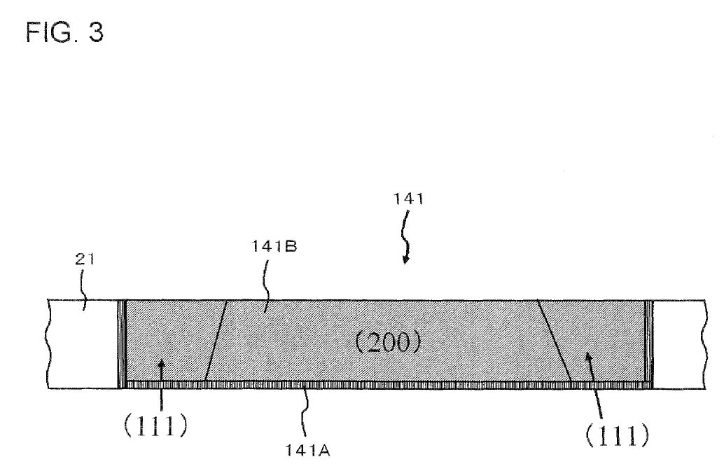

In addition, a thickness T of the inductor 141 is typically, for example, within a range of from 0.5 μm to 4 μm, and an aspect ratio presented by a ratio of (thickness T of inductor 141)/(linewidth W1 of inductor 141) may be preferably equal to or smaller than 0.2. More preferably, the thickness T of the inductor 141 may be within a range of from 0.5 μm to 2 μm. Though the lower limit of the aspect ratio is not particularly determined, the linewidth may be preferably equal to or larger than 0.05, as a two-dimensional area occupied by the inductor 141 is taken into consideration. Such inductor 141 contains copper having plain orientation [200]. In addition, in the inductor 141, as shown in FIG. 3, the size of the grain in the inductor 141 is larger as approaching a center from a side wall of the interconnect trench having the inductor 141 buried therein, along a cross section perpendicular to the elongating orientation of the inductor 141. While the grain size depends upon the location in the inductor 141 where the grain is located, the sizes of the grains in the inductor 141 is larger than the average grain size in the interconnects of other interconnect layers 11 to 13. More specifically, grains of copper having plain orientation [111] are disposed in the side of the side wall of the interconnect trench of the inductor 141, and grains of copper having plain orientation [200] are disposed in the center of the interconnect trench. As discussed later in detail, the distribution of the grains as described above may be achieved in the inductor 141 manufactured via a process for depositing a bias sputter (Cu film) film 140B and then thermal-treating the deposited film. FIG. 3 is a partially enlarged view of the inductor 141 of FIG. 1.

The interconnect layers 11 to 13 containing no inductor is an interconnect layer located under the interconnect layer 14 containing the inductor 141, and composed of, from the side of the semiconductor substrate, the first interconnect layer 11, the second interconnect layer 12 and the third interconnect layer 13.

An interconnect of each of the interconnect layers 11 to 13 includes a copper seed film 101 formed along the interconnect trench and a copper film 102 provided on such copper seed film 101.

A linewidth of the first interconnect layer 11, a linewidth of the second interconnect layer 12 and a linewidth of the third interconnect layer 13 are, for example, 01 μm to 0.8 μm. Respective linewidths of the first interconnect layer 11, the second interconnect layer 12 and the third interconnect layer 13 are smaller than the linewidth W1 of the uppermost interconnect layer 14. The average grain size in the interconnect of the first interconnect layer 11, the average grain size of the second interconnect layer 12 and the average grain size of the third interconnect layer 13 are smaller than the above-described average grain size of the inductor 141. For example, each of the average grain size in the interconnect of the first interconnect layer 11, the average grain size of second interconnect layer 12 and the average grain size of the third interconnect layer 13 are equal to or smaller than one tenth of the average grain size in the inductor 141. More specifically, such average grain size is about 0.01 μm. Here, when it is referred to as simply “average grain size” in the present embodiment, it means number average of the grain sizes of the copper films 141B, 142B and 102. In addition to above, the average grain sizes in the seed films 101 of the first interconnect layer 11, the second interconnect layer 12 and the third interconnect layer 13 in the present embodiment are substantially equivalent to the average grain size in the seed film 141A of the interconnect layer 14.

Next, the process for manufacturing the semiconductor device 1 will be described. Firstly, the interconnect trench is formed in the insulating layer 15, and a copper seed film 101 is provided by a chemical vapor deposition (CVD) process or the like. Thereafter, the copper film 102 is formed on seed film 101 by an electrolytic plating process to fill the interconnect trench.

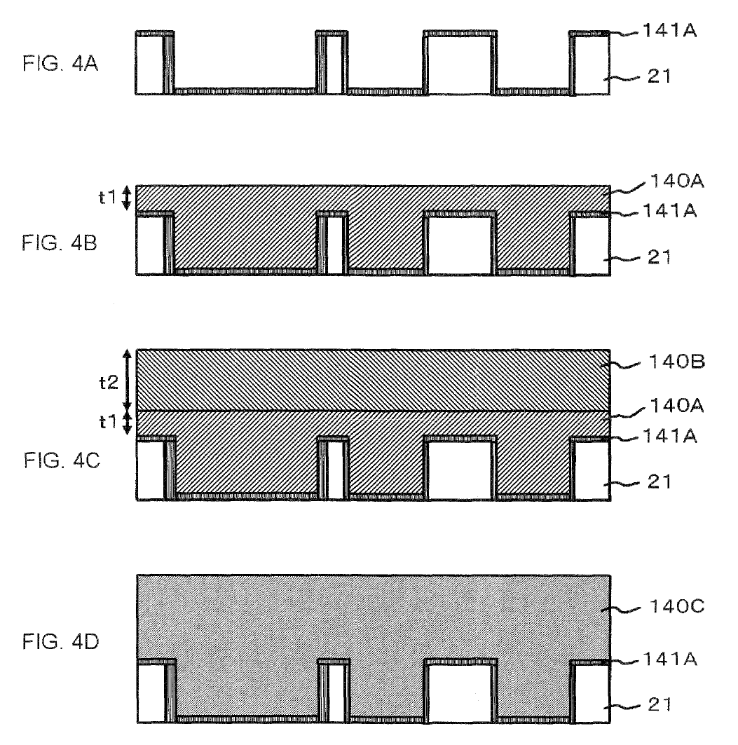

Next, the insulating layer 16 is provided on the insulating layer 15 to form the via V. These operations are repeated to form the second interconnect layer 12 and the associated via V, and the third interconnect layer 13 and the associated via V. Next, the uppermost insulating layer 21 is provided, and the interconnect trench is formed in such insulating layer 21. Now, a process for forming the interconnect layer 14 in the insulating layer 21 will be described in reference to FIGS. 4A to 4D. Here, FIGS. 4A to 4D shows only the interconnect layer 14 and the insulating layer 21 having such interconnect layer 14 provided therein, and underlying interconnect layers or the like are not shown. In addition to above, taken the visibility into consideration, hatching indicating the cross section of the insulating layer is not shown in FIGS. 4A to 4D. First, a barrier metal of TaN film or the like having a thickness of, for example, about 15 nm is provided in the interconnect trench formed in the insulating layer 21 (not shown), and then the seed film 141A of copper is formed on the barrier metal (FIG. 4A). The seed film 141A has a thickness of, for example, 100 nm, and may be deposited via a sputtering process.

Next, the copper film 140A is formed on this seed film 141A by an electrolytic plating process. The thickness of copper film 140A is, for example, 500 nm. The copper film 140A has orientation [111]. Here, total thickness of the seed film 141A and the copper film 140A is defined as t1 (FIG. 4B).

Next, Cu (bias sputter Cu film) film 140B having a thickness t2 is deposited, while applying radio frequency (RF) bias or direct current (DC) bias over the semiconductor substrate and applying argon ion over a sputter-growth surface. In such process, the condition is suitably selected to provide such thickness t2 being larger than the thickness t1 (i.e., t2>t1). The thickness t2 is selected as, for example, 700 nm. In addition, argon ion energy is selected as, for example, 80 eV. Next, a thermal processing is conducted within an atmosphere of argon (Ar) or nitrogen (N₂) for achieving crystal control. For example, the thermal processing is conducted at 400 degree C. for 30 minutes. In such processing, the crystal orientation of copper is changed to Cu [200], and simultaneously, the Cu film 140C containing huge grains is formed (FIG. 4C). Next, copper (Cu) other than the interconnects is removed via a chemical mechanical polishing (CMP) process to form the interconnects. Here, in the present embodiment, while the linewidth W1 of the inductor 141 is selected to be equal to or larger than 5 μm, the linewidth of the interconnects 142 other than the inductor 141 is selected to be equal to or smaller than 3 μm. Therefore, while the average grain size of the inductor 141 is increased, the average grain size of the interconnects 142 other than the inductor 141 is not considerably increased. This is because the grain cannot be grown to be larger when the interconnect width of the trench is narrower.

According to the present embodiment as described above, the following advantageous effects are achieved. The average grain size in the inductor 141 is larger than the average grain size in the interconnects of the copper interconnect layers 11 to 13 containing no inductor. In the conventional semiconductor devices, both of the copper interconnect layer containing inductor and the copper interconnect layer containing no inductor are ordinarily deposited by an electrolytic plating process, and the average grain size in the inductor is equivalent to the average grain size in the interconnect of the interconnect layer containing no inductor. On the other hand, the average grain size of the inductor 141 is larger than the average grain size of the copper interconnect layers 11 to 13, which are deposited by an electrolytic plating process in the present embodiment, and thus the average grain size of the inductor in the embodiment is larger than that of the conventional semiconductor device. Therefore, reduced resistance of the inductor 141 can be achieved and enhanced Q factor can be obtained, as compared with the conventional semiconductor device. For example, in the present embodiment, while a electrical resistivity of the inductor 141 is 1.75 μΩ·cm, a electrical resistivity of the respective interconnects of the copper interconnect layers 11 to 13 are 2.0 μΩ·cm In the present embodiment, reduction of the resistance of the inductor 141 is intended by providing an increased average grain size of the inductor 141. Thus, larger space is not necessary for the inductor 141, which does not cause an obstacle for miniaturization of the semiconductor device 1.

Further, the average grain size of the inductor 141 is equal to or higher than 10 times the average grain size of the interconnects of the copper interconnect layers 11 to 13 containing no inductor. Therefore, reduced resistance of the inductor 141 can be ensured and enhanced Q factor can be obtained, as compared with the conventional semiconductor device, in which the average grain size of the inductor is equivalent to the average grain size of the interconnects of the interconnect layers containing no inductor.

In addition, the linewidth W1 of the inductor 141 is selected to be equal to or larger than 5 μm in the present embodiment. The present inventors previously propose a technology disclosed in Japanese Patent Laid-Open No. 2003-109,960. This attempts to achieve a reduced resistance and an enhanced electromigration resistance of the interconnect by having an increased grain size of the interconnect. The results of the further investigations by the present inventors showed that larger grain size cannot be obtained for smaller linewidth, and thus it was found that a certain dimension of the linewidth is necessary for achieving larger grain size. Conventionally, an inductor is formed to have wider linewidth, in order to achieve a reduced resistance. The present inventors have found that further increased grain size can be achieved by applying the technology described in Japanese Patent Laid-Open No. 2003-109,960 to an inductor having a certain dimension of linewidth, providing a reduced resistance and an enhanced Q factor of the inductor.

From the above-described point of view, the linewidth W1 of the inductor 141 is selected to be equal to or larger than 5 μm, so that the larger average grain size of the inductor 141 would be ensured. Further, the aspect ratio presented by a ratio of (thickness T of inductor 141)/(linewidth W1 of inductor 141) is selected to be equal to or smaller than 0.2 in the present embodiment. In the configuration of smaller aspect ratio, or in other words smaller thickness and wider linewidth of the inductor 141, a use of the process for forming the inductor according to the present embodiment ensures providing larger grain size. Meanwhile, when the aspect ratio of the inductor is larger, the grain size in the bottom of the interconnect trench may not be larger.

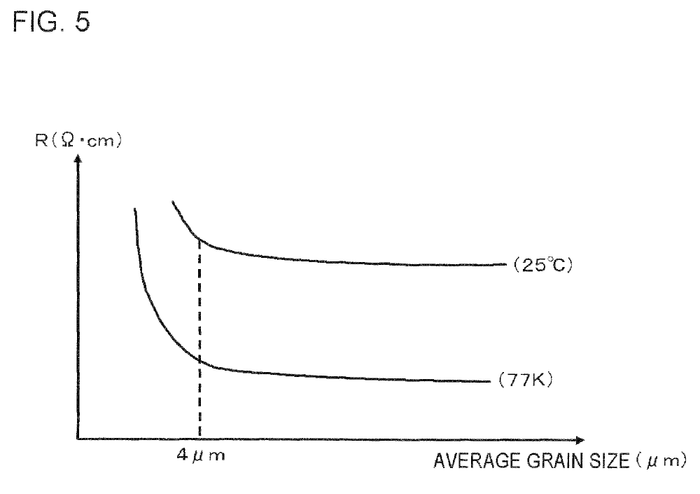

Further, the average grain size of inductor 141 is selected to be equal to or larger than 4 μm, and preferably equal to or larger than 5 μm in the present embodiment. According to the results of the investigations by the present inventors, it was found that the resistance was rapidly decreased when the average grain size of the inductor is equal to or smaller than 4 μm, as shown in FIG. 5. Therefore, the average value of the grain size in the inductor 141 is selected to be equal to or larger than 4 μm, so that the inductor having further reduced resistance would be achieved. Further, in the present embodiment, the size of the grain in the inductor 141 is larger as approaching a center from a side wall of the interconnect trench having the inductor 141 buried therein, along a cross section perpendicular to the elongating orientation of the inductor 141. While the grain size depends upon the location where the grain is located, the sizes of the grains in the inductor of the present embodiment is larger than the average grain size in the inductor deposited by a conventional electrolytic plating process, thereby achieving lower resistance of the inductor 141.

It is intended that the present invention is not limited to the above-described embodiments, and various modifications or improvements thereof are available within the scope that can achieve the purpose of the present invention. For example, while the average grain size in the interconnect 142 of the interconnect layer 14 is smaller than the average grain size in the inductor 141 in the above-described embodiment, the average grain size in the interconnect 142 may alternatively be equivalent to the average grain size in the inductor 141. In order to achieve such configuration, the linewidth of inductor 141 may be selected to be equivalent to the linewidth of the interconnect 142. Further, while the size of the grain in the inductor 141 is larger as approaching a center from a side wall of the interconnect trench having the inductor 141 buried therein, along a cross section perpendicular to the elongating orientation of the inductor 141 in the above-described embodiment, the available configuration of the present invention is not particularly limited thereto, only one grain may be contained along a cross section perpendicular to the elongating orientation of the inductor 141 in the interconnect trench. The manufacture may be conducted by depositing the above-described bias sputter (Cu film) film 140B and conducting a thermally processing, so that the configuration having only one grain contained along a cross section perpendicular to the elongating orientation of the inductor 141 in the interconnect trench would be achieved.

### EXAMPLES

Examples of the present invention will be described below.

The semiconductor device 1 was manufactured by a process similar as employed in the above-described embodiment. More specifically, the insulating layer 15 was deposited on the semiconductor substrate, and the interconnect layer 11 of copper was formed in such insulating layer 15. The linewidth of the interconnect layer 11 was 0.1 μm, and the seed film 101 was deposited by a sputtering process. The thickness of such seed film 101 was 100 nm. The copper film 102 was deposited by an electrolytic plating process. Similar operations were repeated to provide the insulating layers 16 to 21 and form interconnect layers 12 and 13 and the vias V. The interconnect layers 12 and 13 and the seed films 101 in the vias V were deposited via a sputtering process. The thickness of the seed films 101 was 100 nm. The copper films 102 were deposited via an electrolytic plating process. In addition to above, silicon carbonitride (SiCN) films were employed for the insulating layers 15, 17, 19 and 21, and silicon dioxide (SiO₂) films were employed for the insulating layers 16, 18 and 20.

Next, the interconnect trench was formed in the insulating layer 21. The linewidth of the interconnect trench for providing the inductor 141 formed therein was 10 μm, and the linewidth of the interconnect 142 other than the inductor 141 was 2 μm, and the aspect ratio presented by a ratio of (thickness of inductor 141)/(linewidth of inductor 141) was 0.1. Then, the seed film 141A was deposited in the interconnect trench by a sputtering process. The thickness of the seed film 141A was 100 nm. Next, the copper film 140A of a thickness of 500 nm was deposited by an electrolytic plating process. In such case, crystal orientation of the seed film 141A and the copper film 140A was Cu [111]. Next, Ar/H₂ plasma at room temperature within a cleaning chamber was utilized to achieve a chemical reduction of the copper oxide in the surface of the copper film 140A. Then, the substrate was transferred to a copper (Cu)-sputter chamber without being exposed in an atmospheric air, and RF bias voltage or DC bias voltage was applied over the substrate to achieve a sputtered deposition while applying argon ion over the growing surface thereof. This resulted in a formation of Cu (bias-sputtered Cu layer) film 140B on the copper film 140A. The ion energy of argon (plasma potential, i.e., self-bias) in such case was 80 eV. The deposited thickness (t2) was 700 nm, which is larger than the film thickness (t1). That is to say, the thickness was selected as t2>t1. The temperature of the substrate was set to be −5 degree C., in order to prevent an increase in the temperature due to a plasma irradiation during the deposition process.

Next, a thermal processing was conducted within an argon atmosphere at a temperature of 400 degree C. for 30 minutes. In such occasion, the crystal orientation of the inductor 141 was changed from Cu [111] to in Cu [200], and at the same time, the Cu film 140C having huge grains was formed. Next, portions of copper (Cu) other than the interconnects was removed via a chemical mechanical polishing (CMP) process. In such semiconductor device, the average grain size in the inductor 141 was 4 μm. Further, the average grain size in the interconnect of the interconnect layers 11 to 13 was 0.01 μm. Further, the average grain size of the interconnect 142 other than the inductor 141 in the interconnect layer 14 was smaller than the average grain size of the inductor 141.

The grain sizes of the respective grains are obtained by an average of the long axis and the short axis of the grain, and the average grain size is number average of the grain sizes. Here, 2-4 sections perpendicular to the elongating orientation of the interconnect or the inductor ware analyzed, and grains of each section were measured. Number average of the grain sizes of each interconnect and number average of the grain sizes of inductor were calculated.

Further, the inductor 141 contained copper having plain orientation [200], and the size of the grain in the inductor 141 was larger as approaching a center from a side wall of the interconnect trench having the inductor 141 buried therein. Further, grains of copper having plain orientation [111] were arranged in the side of the side wall of the interconnect trench of the inductor, and grains of copper having plain orientation [200] were arranged in the center of the interconnect trench.

Further, while the electrical resistivity of the inductor 141 was 1.75 μΩ·cm, the electrical resistivities of respective interconnects of the copper interconnect layers 11 to 13 were 2.0 μΩ·cm.

It is apparent that the present invention is not limited to the above embodiment, and may be modified and changed without departing from the scope and spirit of the invention.

What is claimed is:

1. A semiconductor device, comprising:
a first copper interconnect layer, having an interconnect including an inductor and buried in an interconnect trench formed in a first insulating layer; and
a second copper interconnect layer containing no inductor and buried in an interconnect trench formed in a second insulating layer, said second copper interconnect layer having a second interconnect, said first and second copper interconnect layers being stacked,
wherein an average grain size of said inductor is larger than an average grain size of said second interconnect of said second copper interconnect layer containing no inductor.

2. The semiconductor device as set forth in claim 1, wherein a linewidth of said inductor along a section perpendicular to an elongating orientation of said inductor is equal to or higher than 5 μm.

3. The semiconductor device as set forth in claim 1, wherein an aspect ratio presented by (the thickness of said inductor)/(the linewidth of said inductor) is equal to or lower than 0.2.

4. The semiconductor device as set forth in claim 1, wherein an average grain size of said inductor is equal to or larger than 4 μm.

5. The semiconductor device as set forth in claim 1, wherein said inductor contains copper having plain orientation [200].

6. The semiconductor device as set forth in claim 1, wherein the size of the grain contained in said inductor is larger as approaching a center from a side wall of said interconnect trench along a cross section perpendicular to the elongating orientation of said inductor, said interconnect trench having said inductor buried therein.

7. The semiconductor device as set forth in claim 1, wherein, in a cross section perpendicular to the elongating orientation of said inductor, grains of copper having plain orientation [111] are disposed in a side of the side wall of said interconnect trench of said inductor, and grains of copper having plain orientation [200] are disposed in the central portion of said interconnect trench.

8. The semiconductor device as set forth in claim 1, wherein, the average grain size of said inductor is equal to or higher than 10 times the average grain size of the interconnect of said second copper interconnect layer containing no inductor.
